(19) United States
(12) Patent Application Publication
(10) Pub. No.: US 2025/0341783 A1
(43) Pub. Date: Nov. 6, 2025

(54) EXPOSURE METHOD, EXPOSURE DEVICE, AND DEVICE MANUFACTURING METHOD

(71) Applicant: NIKON CORPORATION, Tokyo (JP)

(72) Inventor: Yoji WATANABE, Tokyo (JP)

(73) Assignee: NIKON CORPORATION, Tokyo (JP)

(21) Appl. No.: 19/272,755

(22) Filed: Jul. 17, 2025

Related U.S. Application Data
(63) Continuation of application No. PCT/JP2023/004244, filed on Feb. 8, 2023.

(51) Int. Cl. G03F 7/00

(52) U.S. Cl. CPC G03F 7/70308; G03F 7/70358; G03F 7/70525; G03F 7/70575

(57) ABSTRACT

An exposure method includes illuminating a first object with exposure light including first exposure light having a first peak wavelength and second exposure light having a second peak wavelength, the second peak wavelength being different from the first peak wavelength, and exposing a second object with the exposure light from the first object, wherein a ratio between an intensity of the second exposure light with which the second object is irradiated and an intensity of the first exposure light with which the second object is irradiated is variable, and the intensity of the second exposure light with which the second object is irradiated is set to be higher than the intensity of the first exposure light with which the second object is irradiated.

### CROSS-REFERENCE TO RELATED APPLICATION

This application is a continuation application of the prior International Patent Application No. PCT/JP2023/004244, filed on Feb. 8, 2023, the entire contents of which are incorporated herein by reference.

### FIELD

The present disclosure relates to an exposure method, an exposure device, and a device manufacturing method.

### BACKGROUND

In a lithography process in the manufacture of microdevices (electronic devices or the like) such as semiconductor elements, liquid crystal display elements, and the like, there are cases where a pattern having a large depth relative to a width (high aspect ratio), that is, a so-called groove, is exposed on a photosensitive material layer on a substrate (glass plate, semiconductor wafer, or the like) as disclosed in, for example, U.S. Patent Application Publication No. 2019/0204756 (Patent Document 1).

### SUMMARY

According to a first aspect of the present disclosure, there is provided an exposure method including: illuminating a first object with exposure light including first exposure light having a first peak wavelength and second exposure light having a second peak wavelength, the second peak wavelength being different from the first peak wavelength; and exposing a second object with the exposure light from the first object, wherein a ratio between an intensity of the second exposure light with which the second object is irradiated and an intensity of the first exposure light with which the second object is irradiated is variable, and the intensity of the second exposure light with which the second object is irradiated is set to be higher than the intensity of the first exposure light with which the second object is irradiated.

According to a second aspect of the present disclosure, there is provided an exposure method including: illuminating a first object with exposure light including first exposure light having a first peak wavelength and second exposure light having a second peak wavelength, the second peak wavelength being different from the first peak wavelength; and exposing a second object moving along a scanning direction with the exposure light from the first object, wherein a timing at which the second object is irradiated with the second exposure light is different from a timing at which the second object is irradiated with the first exposure light.

According to a third aspect of the present disclosure, there is provided an exposure device including: an illumination optical system that illuminates a first object with exposure light including first exposure light having a first peak wavelength and second exposure light having a second peak wavelength, the second peak wavelength being different from the first peak wavelength; and a projection optical system that projects the exposure light from the first object onto a second object, wherein a ratio between an intensity of the second exposure light with which the second object is irradiated and an intensity of the first exposure light with which the second object is irradiated is variable, and the intensity of the second exposure light with which the second object is irradiated is set to be higher than the intensity of the first exposure light with which the second object is irradiated.

According to a fourth aspect of the present disclosure, there is provided an exposure device that scans and exposes a pattern of a first object onto a second object, the exposure device including: an illumination optical system that illuminates a first object with exposure light including first exposure light having a first peak wavelength and second exposure light having a second peak wavelength, the second peak wavelength being different from the first peak wavelength; a projection optical system that projects the exposure light from the first object onto a second object moving along a scanning direction; and a control device that controls a light source that supplies the exposure light to the illumination optical system, wherein the control device performs control such that a timing at which the second object is irradiated with the second exposure light is different from a timing at which the second object is irradiated with the first exposure light.

According to a fifth aspect of the present disclosure, there is provided a device manufacturing method including: exposing a photosensitive material layer of a second object by using the above exposure method; and processing a part further in than the photosensitive material layer of the second object by using a pattern generated by developing the photosensitive material layer, which has been exposed, as a mask.

The configuration of the embodiments described below may be modified appropriately, and at least one or some of the components may be substituted for other components. Further, the constituent elements whose arrangement is not particularly limited are not limited to the arrangement disclosed in the embodiments, and can be arranged at positions where the functions can be achieved.

### BRIEF DESCRIPTION OF DRAWINGS

FIG. 1 schematically illustrates a configuration of an exposure device according to an embodiment;

FIG. 2A schematically illustrates a configuration of a light source unit, and FIG. 2B illustrates the wavelength of a light beam emitted from each solid-state laser light source;

FIG. 3 illustrates an example of a spatial light modulator;

FIG. 4A and FIG. 4B are diagrams for describing axial chromatic aberration;

FIG. 5A schematically illustrates a mask used in a simulation, and FIG. 5B schematically illustrates a substrate and a resist used in the simulation;

FIG. 6A to FIG. 6E illustrate simulation results of the intensity distribution of a pattern image formed in a resist when the resist is irradiated with light beams L1 to light L5 at the same intensity;

FIG. 7 illustrates a relationship between the wavelength and the intensity of light in the embodiment;

FIG. 8 illustrates simulation results of the intensity distribution of a pattern image formed in a resist when a mask is illuminated with illumination light in which the intensity of each of the light beams L1 to L5 is adjusted;

FIG. 9A and FIG. 9B illustrate simulation results of the NILS, uniformity, and number of wavelengths at each k₂ when the numerical aperture NA is 0.4 and 0.5, respectively;

FIG. 10A and FIG. 10B illustrate simulation results of the NILS, uniformity, and number of wavelengths at each k₂ when the numerical aperture NA is 0.6 and 0.7, respectively;

FIG. 11A illustrates simulation results of the NILS, uniformity, and number of wavelengths at each k₂ when the numerical aperture NA is 0.8, and FIG. 11B illustrates simulation results of the NILS and uniformity at each k₂ when the numerical aperture NA is 1.35;

FIG. 12 is a diagram for describing magnification chromatic aberration;

FIG. 13A illustrates a distribution of magnification chromatic aberration of the projection optical system, and FIG. 13B illustrates a distribution of magnification chromatic aberration after scan averaging;

FIG. 14A and FIG. 14B illustrate simulation results of the intensity distribution of a combined pattern image after scan averaging, wherein FIG. 14A illustrates the intensity distribution on a plane perpendicular to a Y axis, and FIG. 14B illustrates the intensity distribution on a plane perpendicular to an X axis;

FIG. 15 illustrates emission timings of the light beams L1 to light L5;

FIG. 16 illustrates simulation results of the intensity of a combined pattern image in a cross section orthogonal to the X axis, which is obtained by shifting the emission timings of the light beam L1 to the light beam L5 as illustrated in FIG. 15; and

FIG. 17A to FIG. 17C illustrate simulation results of the intensity of a combined pattern image formed in a resist by methods according to Comparative Examples 1 to 3, and FIG. 17D illustrates a simulation result of the intensity of a combined pattern image formed in a resist by the method according to the present embodiment.

### DESCRIPTION OF EMBODIMENTS

It is desired to form a pattern having a high aspect ratio in which the width is constant in a depth direction and the inclination of the inner wall is small in a photosensitive material layer on a substrate (a glass plate, a semiconductor wafer, or the like).

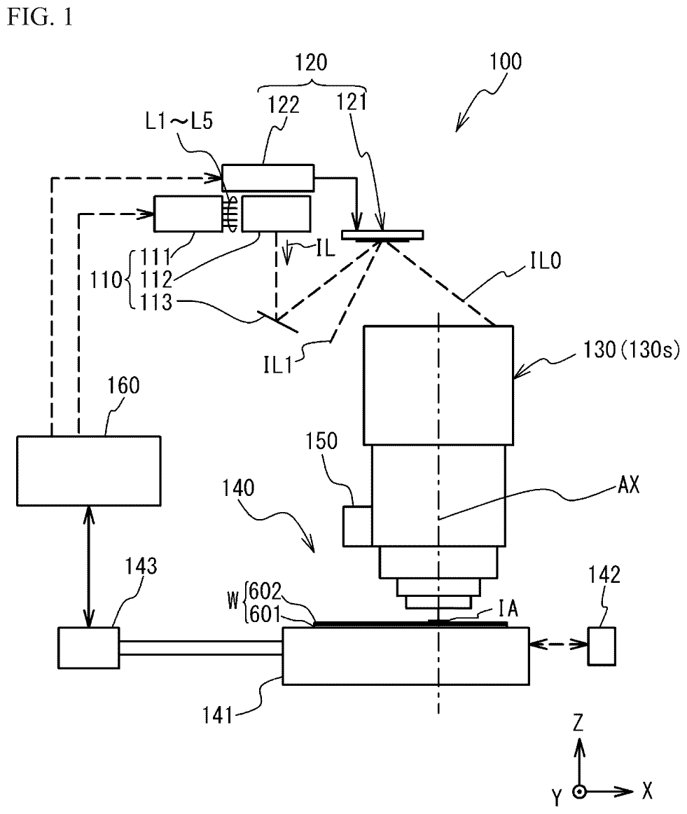

Hereinafter, an exposure device 100 according to a present embodiment will be described with reference to FIG. 1 to FIG. 16.

FIG. 1 schematically illustrates a configuration of the exposure device 100 according to the present embodiment. The exposure device 100 is an exposure device that uses a spatial light modulator (SLM) that modulates illumination light (exposure light) according to control by an exposure control unit 160 described later.

As illustrated in FIG. 1, the exposure device 100 includes an illumination system 110, a pattern generation device 120, a projection optical system 130, a stage device 140, an alignment detection system 150, and the exposure control unit 160. In the description of the exposure device 100, two directions orthogonal to each other in a horizontal plane are defined as an X direction and a Y direction, and a direction orthogonal to the X direction and the Y direction is defined as a Z direction. Further, the rotation (inclination) directions about the X axis, the Y axis, and the Z axis are defined as a Ox direction, a Oy direction, and a Oz direction, respectively. In the present embodiment, the X direction is the scanning direction.

The illumination system 110 includes a light source unit 111, an illumination optical system 112, and a reflection mirror 113.

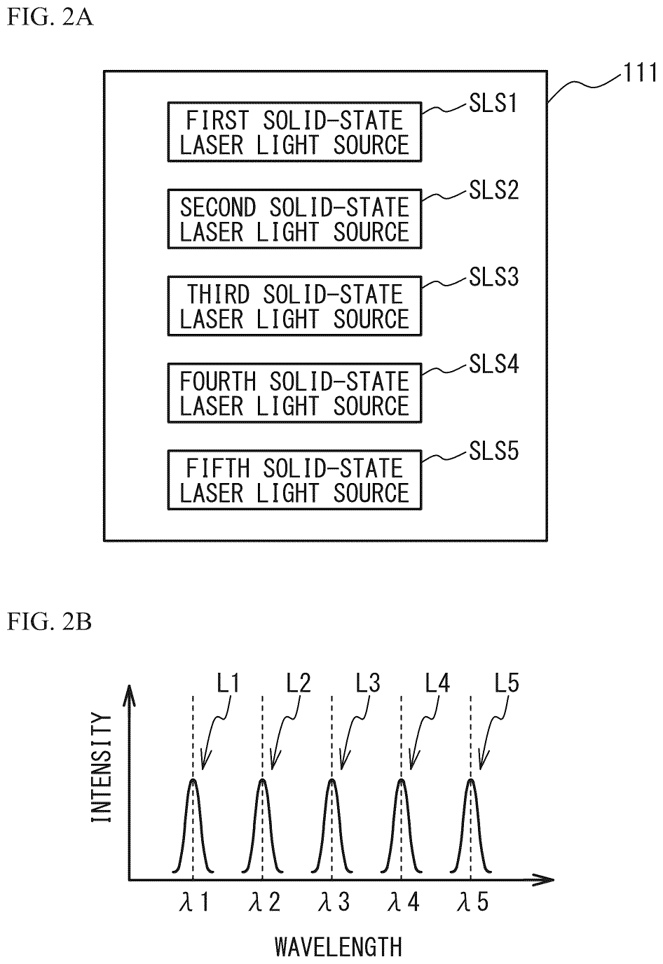

FIG. 2A schematically illustrates a configuration of the light source unit 111. The light source unit 111 includes a plurality of solid-state laser light sources. In the present embodiment, the light source unit 111 includes a first solid-state laser light source SLS1, a second solid-state laser light source SLS2, a third solid-state laser light source SLS3, a fourth solid-state laser light source SLS4, and a fifth solid-state laser light source SLS5. Each of the solid-state laser light sources SLS1 to SLS5 may be a solid-state laser device that amplifies laser light emitted from a laser light source such as a DFB semiconductor laser by a fiber optical amplifier and wavelength-converts the amplified laser light by a wavelength conversion element. Such a solid-state laser device is disclosed in, for example, U.S. Pat. Nos. 7,339,661, 7,974,320, 9,153,934, 9,160,132, and the like.

The first solid-state laser light source SLS1 emits illumination light (exposure light) L1 having a peak wavelength λ1, with which a spatial light modulator 121 described later is illuminated. The second solid-state laser light source SLS2 emits illumination light (exposure light) L2 having a peak wavelength λ2, with which the spatial light modulators 121 is illuminated. The third solid-state laser light source SLS3 emits illumination light (exposure light) L3 having a peak wavelength λ3, with which the spatial light modulator 121 is illuminated. The fourth solid-state laser light source SLS4 emits illumination light (exposure light) L4 having a peak wavelength λ4, with which the spatial light modulator 121 is illuminated. The fifth solid-state laser light source SLS5 emits illumination light (exposure light) L5 having a peak wavelength λ5, with which the spatial light modulator 121 is illuminated. In the following description, the illumination light L1 to the illumination light L5 are referred to as a light beam L1 to a light beam L5, respectively.

FIG. 2B illustrates the respective peak wavelengths λ1 to λ5 of the light beams L1 to L5 emitted from the first to fifth solid-state laser light sources SLS1 to SLS5, respectively. As illustrated in FIG. 2B, the peak wavelengths λ1 to λ5 are discrete, and in the present embodiment, λ1<λ2<λ3<λ4<λ5. In FIG. 2B, the respective intensities of the light beams L1 to L5 are illustrated as the same for the sake of simplicity, but the intensities of the light beams L1 to L5 will be described later. In FIG. 2B, the intervals between adjacent peak wavelengths are the same, but this does not intend to suggest any limitation. The intervals between adjacent peak wavelengths may be irregular. The first to fifth solid-state laser light sources SLS1 to SLS5 change the intensity of a light beam to be emitted and the emission timing of the light beam based on the instructions from the exposure control unit 160. The instruction from the exposure control unit 160 may be referred to as a trigger signal.

The illumination optical system 112 includes a shaping optical system for changing an illumination condition, an optical integrator, a field stop, and a relay lens system (none of which is illustrated). The illumination optical system 112 emits illumination light (exposure light) IL including the light beams L1 to L5 emitted from the light source unit 111. Since the illumination light IL includes the light beams L1 to L5, the illumination light IL can be said to be light having a plurality of peak wavelengths or light having a discrete distribution of wavelengths.

The pattern generation device 120 generates a pattern to be formed on a wafer W placed on a stage 141 (to be described later) of the stage device 140 under the control of the exposure control unit 160. In the present embodiment, the wafer W includes a base material 601 and a resist 602 (photosensitive material layer) applied on the base material 601.

The pattern generation device 120 includes the spatial light modulator 121 and a drive unit 122.

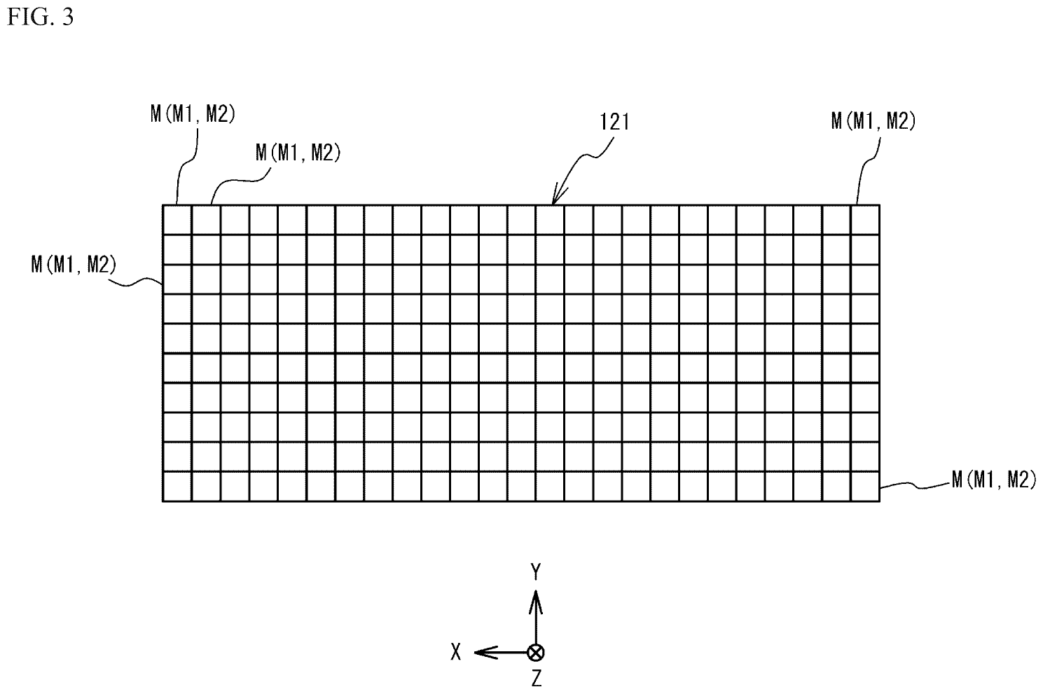

FIG. 3 illustrates an example of the spatial light modulator 121. As illustrated in FIG. 3, the spatial light modulator 121 has a plurality of micromirror mechanisms M arranged in a matrix (two dimensionally, in an array) in an X-Y plane, for example. Each of the micromirror mechanisms M has a micromirror M1 and a drive mechanism M2 provided at the opposite side of the reflecting surface of the micromirror M1. The drive mechanism M2 moves the micromirror M1 (up and down) along an axis extending in the Z direction.

The drive unit 122 drives the drive mechanism M2 of each of the micromirror mechanisms M according to the control signal from the exposure control unit 160, and switches the micromirror M1 between an ON state (ON position) and an OFF state (OFF position).

Here, since the size of each micromirror M1 is too small to be resolved by the projection optical system 130, when all micromirrors M1 are in the ON state or the OFF state in the region of the size that can be resolved by the projection optical system 130, zeroth-order diffracted light IL0 of the illumination light IL incident on the region from the illumination system 110 enters the projection optical system 130. For example, 2× 2 micromirrors M1 may be located in a region of a size that can be resolved by the projection optical system 130. On the other hand, when the illumination light (exposure light) IL from the illumination system 110 enters the region where the micromirrors M1 in the ON state and the micromirrors M1 in the OFF state are alternately located, the illumination light IL is diffracted in this region, zeroth-order diffracted light IL0 of the illumination light IL almost disappears, and the ±1st or higher order diffracted light IL1 of the illumination light IL reaches the non-exposure optical path off the projection optical system 130. The pattern generation device 120 sets each of the micromirrors M1 to either an ON state or an OFF state, thereby giving a pattern to the illumination light IL. In the following description, the surface on which the micromirrors M1 set to either the ON state or the OFF state are arranged may be referred to as a light modulation surface of the spatial light modulator 121.

The spatial light modulator 121 is not limited to the above-described piston type, and may be, for example, a magneto optic spatial light modulator (MOSLM), a digital mirror device (DMD), or the like. Further, although the spatial light modulator 121 has been described as a reflection type that reflects the illumination light IL, the spatial light modulator 121 may be a transmission type that transmits the illumination light IL or may be a diffraction type that diffracts the illumination light IL. The spatial light modulator 121 may be any modulator as long as it can spatially and temporally modulate the illumination light IL.

The projection optical system 130 projects an image of the light modulation surface of the spatial light modulator 121 onto the wafer W placed on the stage 141 at a reduced projection magnification β (for example, β=1/200, 1/400, 1/500, or the like). That is, an exposure pattern is formed on the wafer W by the energy beam via the pattern generation device 120. The projection optical system 130 includes a lens barrel 130s and a plurality of optical elements (not illustrated) disposed in a predetermined positional relationship inside the lens barrel 130s.

The stage device 140 includes the stage (substrate stage) 141, a laser interferometer 142, and a stage driving unit 143.

The stage 141 holds the wafer W via a wafer holder (not illustrated) provided at the center of the upper surface of the stage. The stage 141 can move in the X direction, the Y direction, and the Z direction by the stage driving unit 143, and is rotatable about an axis extending in the Z direction.

The laser interferometer 142 emits a length measurement beam to the reflecting surface provided on each of the end surfaces of the stage 141 in the X direction and the Y direction, thereby constantly detecting the positions of the stage 141 in the X direction, the Y direction, and the Oz direction with a resolution of, for example, about 0.5 to 1 nm.

The stage driving unit 143 drives the stage 141 in accordance with a control signal from the exposure control unit 160.

The alignment detection system 150 is arranged on a side surface of the projection optical system 130. In this embodiment, an imaging alignment sensor is used as the alignment detection system 150. The detailed configuration of the alignment detection system 150 is disclosed in, for example, U.S. Pat. No. 5,637,129.

The alignment detection system 150 detects street lines or position detection marks formed on the wafer W. The detection results of the street lines or the position detection marks by the alignment detection system 150 are output to the exposure control unit 160.

The exposure control unit 160 controls the operations of the illumination system 110, the pattern generation device 120, the stage device 140, and the like so as to form a predetermined exposure pattern on the wafer W, and projects an image of the light modulation surface of the spatial light modulator 121 onto the wafer W held by the stage 141 via the projection optical system 130.

When the spatial light modulator 121 is illuminated with the illumination light IL from the illumination system 110, the illumination light IL reflected by the micromirrors M1 of the spatial light modulator 121, that is, the illumination light IL to which a pattern is given by the spatial light modulator 121 enters the projection optical system 130, and a reduced image (partially inverted image) of the pattern is formed in a projection area IA on the wafer W held on the stage 141.

In the present embodiment, the exposure control unit 160 performs exposure by a step-and-scan method. Further, the exposure control unit 160 scrolls the pattern generated by the spatial light modulator 121 (that is, changes the shape of the pattern generated by the spatial light modulator 121) in synchronization with the movement of the stage 141 while moving the stage 141 at an appropriate speed during the scanning exposure.

As the exposure device 100 having the configuration described above, an exposure device disclosed in U.S. Pat. No. 8,089,616, U.S. Patent Application Publication No. 2020/00257205, or International Publication No. 2005/081034 may be used.

Next, control executed by the exposure control unit 160 according to the present embodiment will be described in detail. In the present embodiment, the exposure control unit 160 executes intensity control and emission timing control of the light beams L1 to L5. First, the intensity control will be described.

In the present embodiment, the spatial light modulator 121 is illuminated with the illumination light IL including a plurality of light beams having different peak wavelengths, and the illumination light IL patterned by the spatial light modulator 121 is projected onto the wafer W.

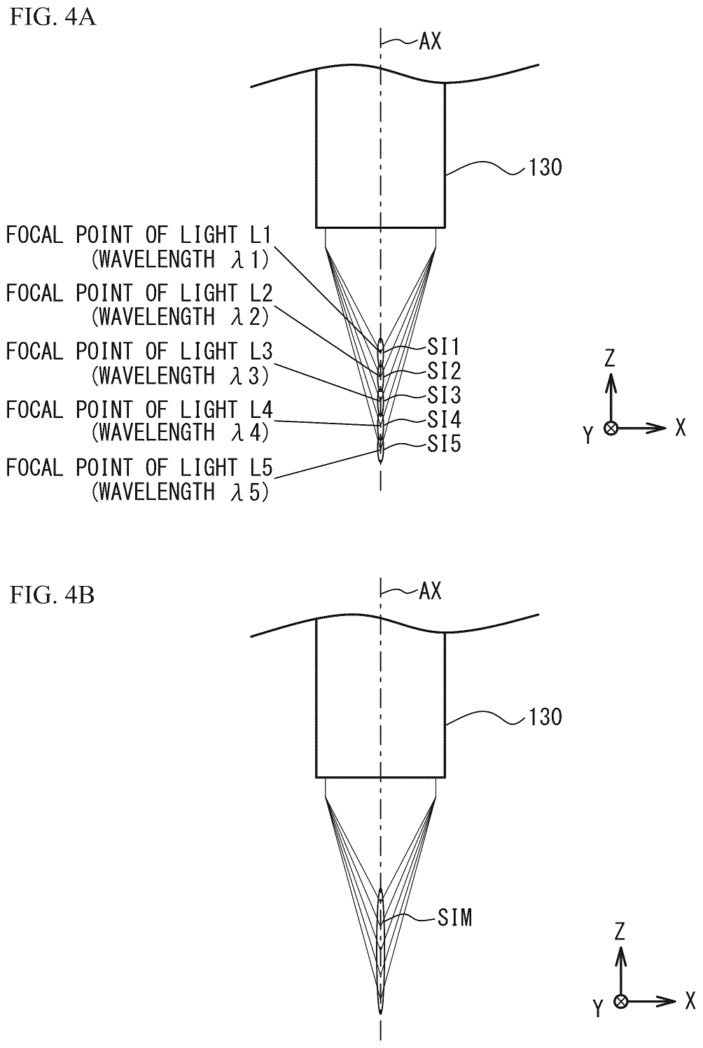

Here, since the light beams L1 to L5 included in the illumination light IL have different peak wavelengths from each other, axial chromatic aberration in which the imaging position (focal point) is shifted in the Z direction occurs due to the projection optical system 130 as illustrated in FIG. 4A. In the present embodiment, in the traveling direction of the light beams L1 to L5, the imaging positions of the light beam L5, the light beam L4, the light beam L3, the light beam L2, and the light beam L1 are located in this order from farthest to closest to the projection optical system 130 (farther from the projection optical system 130 in the order of the light beams L5 to L1). That is, in the traveling direction of the light beams L1 to L5, the imaging position of the light beam L1 with the wavelength λ1 is the closest to the projection optical system 130, and the imaging position of the light beam L5 with the wavelength λ5 is the farthest from the projection optical system 130. In other words, in the traveling direction (−Z direction) of the light beams L1 to L5, the imaging position of the light beam L1 with the wavelength λ1 is the closest to the surface of the resist 602 (photosensitive material layer) of the wafer W (front face of the wafer W), and the imaging position of the light beam L5 with the wavelength λ5 is the farthest from the surface of the resist 602.

Accordingly, the positions where the images SI1 to SI5 of the pattern generated by the spatial light modulator 121 by the light beams L1 to L5 from the spatial light modulator 121 (hereinafter also referred to as pattern images of the light beams L1 to L5) are formed are farther from the surface of the resist 602 of the wafer W in the order of the light beam L5, the light beam L4, the light bema L3, the light beam L2, and the light beam L1 in the traveling direction of the light beams L1 to L5. When the magnification chromatic aberration of the projection optical system 130 is ignored, the pattern images SI1 to SI5 of the light beams L1 to L5 overlap in a direction intersecting the optical axis AX as illustrated in FIG. 4A.

As a result, as illustrated in FIG. 4B, the combined pattern image SIM obtained by combining the five pattern images SI1 to SI5 of the light beams L1 to L5 is an image having a large depth (length in the Z direction) with respect to the width (length in the X direction). In this manner, by using the illumination light IL including a plurality of the light beams L1 to L5 having different peak wavelengths, a pattern (groove) having a high aspect ratio can be formed on the resist 602 of the wafer W.

However, the inventor has found that, when the light beams L1 to L5 are emitted at the same intensity, the intensity of the pattern image of the light beam is weakened as the imaging position of the light beam is farther from the surface of the resist 602 due to the attenuation coefficient of the resist 602. This point will be described in more detail.

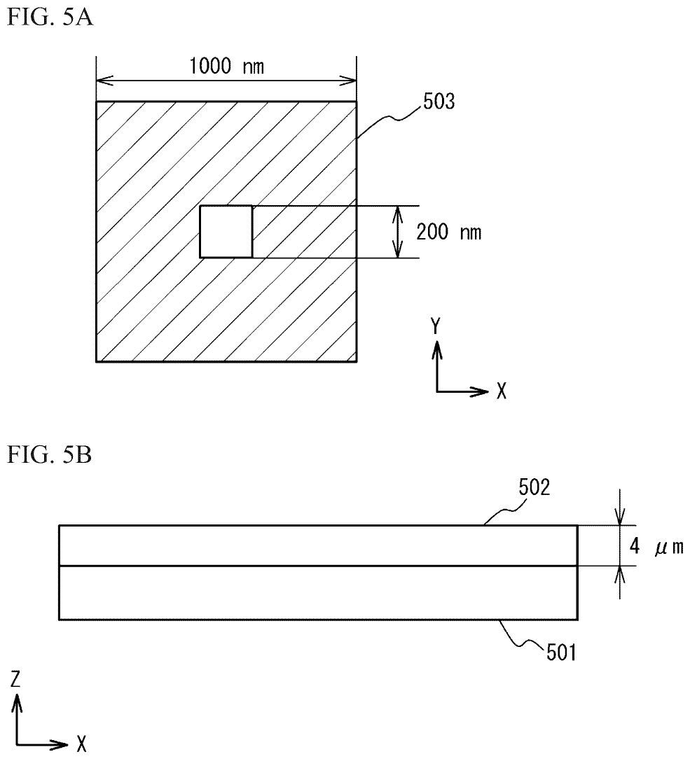

The inventor simulated the intensity of a pattern image formed in a resist 502 applied on a substrate 501 illustrated in FIG. 5B by each of the light beams L1 to L5 having the same intensity through a mask 503 when the mask 503 having a pattern illustrated in FIG. 5A is illuminated with each of the light beams L1 to L5. As illustrated in FIG. 5A, the mask 503 has a square pattern with a one side of 200 nm. In FIG. 5A, a hatched portion indicates that the light transmittance is zero.

In the simulation, the numerical aperture (NA) was assumed to be 0.8. Further, the refraction index of the substrate 501 was assumed to be 1.72, the attenuation coefficient was assumed to be 0.005, and the substrate 501 was assumed not to reflect the light beams L1 to L5. The thickness of the resist 502 was assumed to be 4 μm, the refractive index of the resist 502 was assumed to be 1.72, and the attenuation coefficient was assumed to be 0.005.

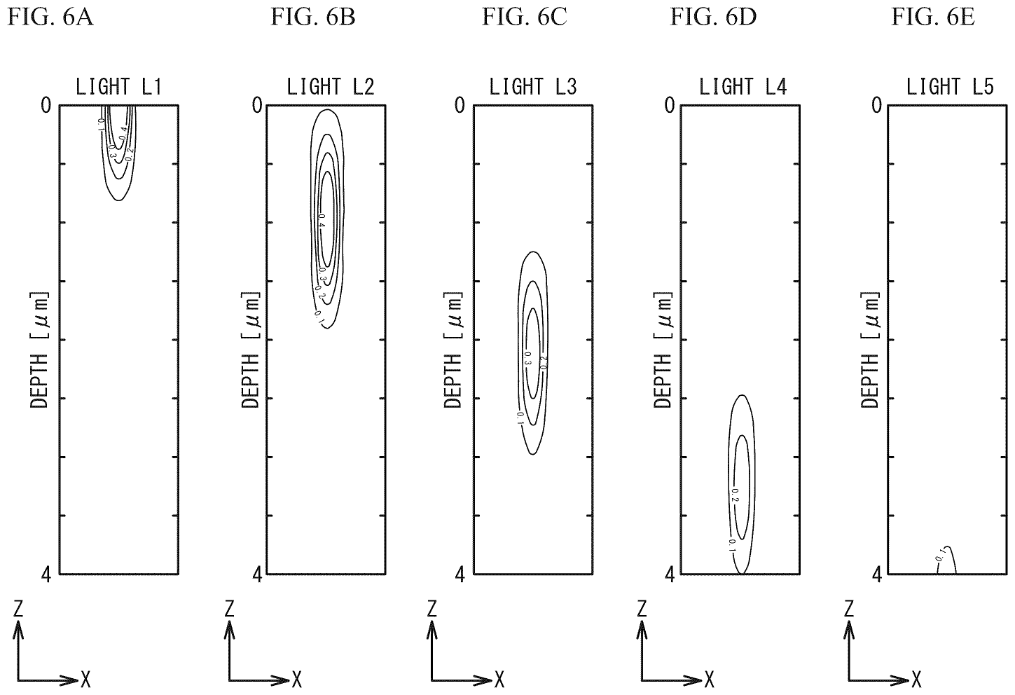

FIG. 6A to FIG. 6E illustrate the simulation results of the intensity distributions of the pattern images of the light beams L1 to L5 in the resist 502 when the light beams L1 to L5 have the same intensity, respectively. Here, due to the axial chromatic aberration of the projection optical system 130, the focal position of the light beam Ln+1 is located at a position deeper than the focal position of the light beam Ln by about 1160 nm (n=1 to 4). FIG. 6A to FIG. 6E illustrate the intensity distributions of the pattern images of the light beams L1 to L5 in the resist 502 with contour lines, and the numbers on the contour lines mean the intensity. The higher numerical value on the contour line means higher intensity.

As illustrated in FIG. 6A to FIG. 6E, due to the influence of the attenuation coefficient of the resist 502, as the formation position of the pattern image is farther from the surface of the resist 502, the intensity of the pattern image becomes smaller.

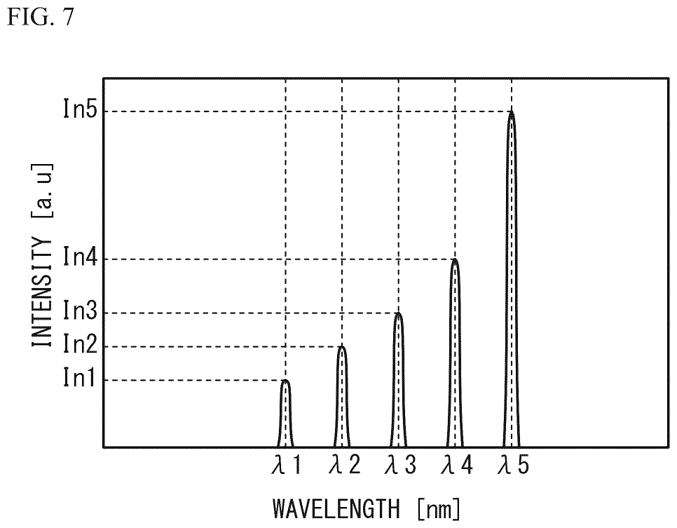

Therefore, in the present embodiment, the intensities of the light beams L1 to L5 when the light beams L1 to L5 enter the illumination optical system 112 are made different from each other. Specifically, as illustrated in FIG. 7, the intensity is increased as the imaging position is located farther from the surface of the resist 602 in the traveling direction of the light beams L1 to L5, that is, as the respective formation positions of the respective pattern images of the light beams L1 to L5 are located farther from the surface of the resist 602. In other words, the intensity of the light beam irradiated onto the wafer W is increased as the formation position of the pattern image thereof is located farther from the surface of the resist 602.

In the present embodiment, in the traveling direction of the light beams L1 to L5, the formation positions of the pattern images of the light beams L1 to L5 are farther from the surface of the resist in the order of the light beams L5 to L1. Therefore, when the intensity of the light beam L1 is denoted by In1, the intensity of the light beam L2 is denoted by In2, the intensity of the light beam L3 is denoted by In3, the intensity of the light beam L4 is denoted by In4, and the intensity of the light beam L5 is denoted by In5, the relationship In1<In2<In3<In4<In5 is satisfied. Accordingly, the intensities of the light beams L1 to L5 irradiated to the wafer W are higher in the order of the light beams L5 to L1.

The respective intensities In1 to In5 of the light beams L1 to L5 can be adjusted by, for example, the exposure control unit 160 controlling the first to fifth solid-state laser light sources SLS1 to SLS5. For example, the respective intensities In1 to In5 of the light beams L1 to L5 may be adjusted by setting of the first to fifth solid-state laser light sources SLS1 to SLS5.

The intensities In1 to In5 of the light beams L1 to L5 may be adjusted using a neutral density filter in addition to the control or setting of the first solid-state laser light sources SLS1 to SLS5. Further, the intensities of the light beams L1 to L5 emitted from the first to fifth solid-state laser light sources SLS1 to SLS5 may be adjusted to be the same, and the intensities In1 to In5 of the light beams L1 to L5 when the light beams L1 to L5 enter the illumination optical system 112 (the intensities when being irradiated to the wafer W) may be adjusted to satisfy the relationship In1<In2<In3<In4<In5 by the neutral density filter.

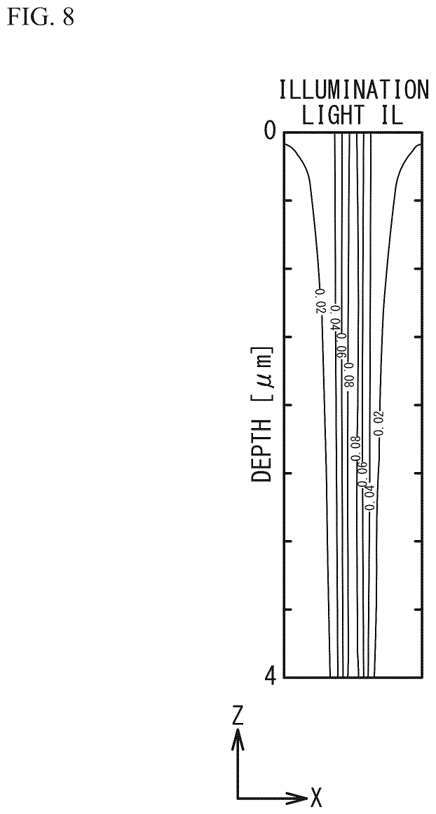

FIG. 8 illustrates simulation results of the intensity distribution of a combined pattern image formed in the resist 502 when the mask 503 is illuminated with the illumination light IL in which the respective intensities of the light beams L1 to L5 in FIG. 6A to FIG. 6E are adjusted. The intensity Isum of the combined pattern image is calculated by the following formula.

$$Isum = \sum Ini \cdot I ( λ i )$$

Here, Ini (i=1 to 5) is a weighting factor, and I(λi) is the intensity of the light beam Li (i=1 to 5) when emitted from the solid-state laser light source. Therefore, Ini·I(λi) is the intensity of the light beam Li when the mask 503 is illuminated (or the intensity of the light beam Li when the resist 502 is irradiated with). In the simulation of FIG. 8, In1=0.077, In2=0.116, In3=0.164, In4=0.232, and In5=0.411.

As illustrated in FIG. 8, it is understood that a combined pattern image having a uniform intensity in the depth direction of the resist 502 is formed by satisfying the relationship In1<In2<In3<In4<In5.

The interval Δλ between the wavelengths of the light beams L1 to L5 is determined so that the normalized image log slope (NILS) in the X direction and the Y direction of the combined pattern image obtained by combining the pattern images of the light beams is high, the non-uniformity in the Z direction of the intensity of the combined pattern image is small (the uniformity is high), and the number of wavelengths to be used is small. When a difference between the position of the focal point of the light beam having a wavelength λ and the position of the focal point of the light beam having a wavelength λ+Δλ is denoted by ΔFocus,

$$ΔFocus = {k}_{2} \cdot λ / {NA}^{2} = Cz \cdot Δλ , \\ Δλ = {k}_{2} \cdot λ / Cz \cdot {NA}^{2} .$$

Therefore, the interval Δλ between the wavelengths can be converted into k₂. Here, Cz represents the axial chromatic aberration, NA represents the numerical aperture, and λ represents representative (specific) wavelength (for example, 248 nm) within a range including the wavelengths λ1 to λ5 of the light beams L1 to L5.

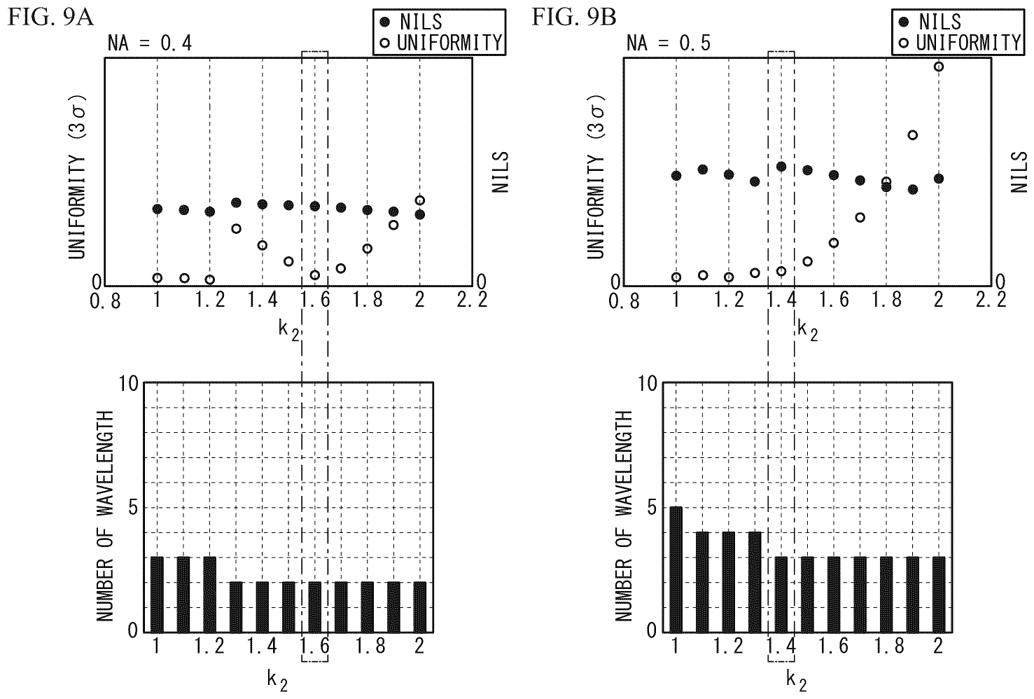

A simulation was performed to determine the optimum k₂. FIG. 9A to FIG. 11B illustrate the simulation results of the NILS, uniformity, and number of wavelengths at each k₂ when the numerical aperture NA is 0.4, 0.5, 0.6, 0.7, 0.8, and 1.35, respectively.

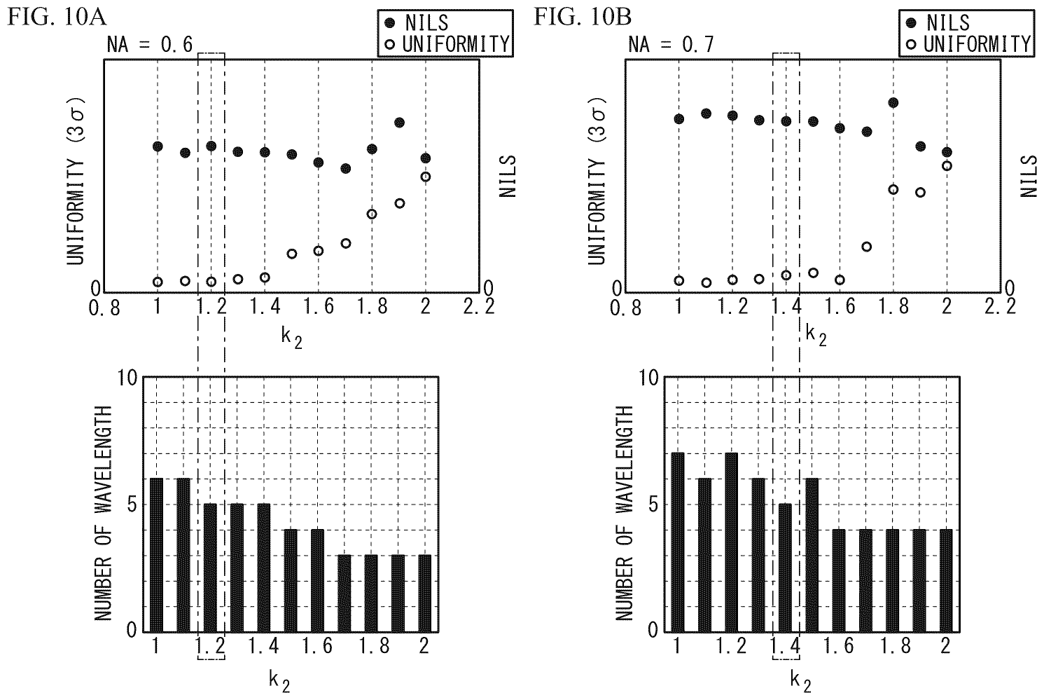

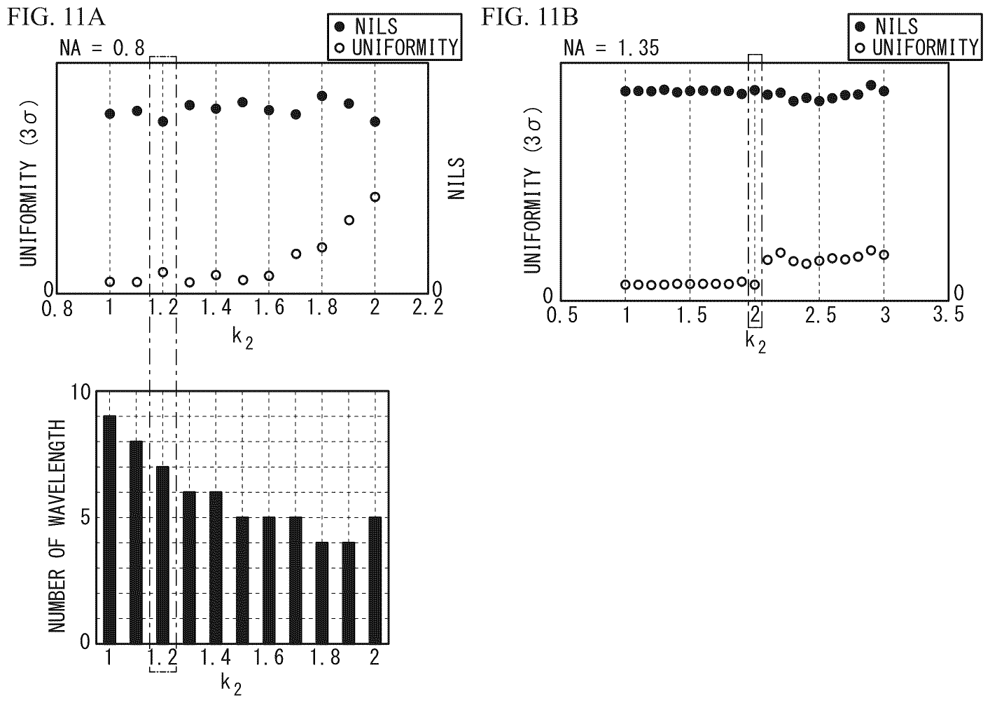

As described above, the NILS of the combined pattern image in the X direction and the Y direction is preferably high, the non-uniformity of the intensity of the combined pattern image in the Z direction is preferably small (the uniformity is preferably high), and the number of wavelengths to be used is preferably small. Therefore, as illustrated in FIG. 9A, when the numerical aperture NA is 0.4, it is considered that k₂ is optimally 1.6. As illustrated in FIG. 9B, when the numerical aperture NA is 0.5, it is considered that k₂ is optimally 1.4. As illustrated in FIG. 10A, when the numerical aperture NA is 0.6, it is considered that k₂ is optimally 1.2. As illustrated in FIG. 10B, when the numerical aperture NA is 0.7, it is considered that k₂ is optimally 1.4. As illustrated in FIG. 11A, when the numerical aperture NA is 0.8, it is considered that k₂ is optimally 1.2.

As described above, when the numerical aperture NA is less than 1, the interval between wavelengths is preferably Δλ satisfying k₂=1.2 to 1.6.

As illustrated in FIG. 11B, when the numerical aperture NA is 1.35, it is considered that k₂ can be adjusted to be about 2.

Next, emission timing control of the light beams L1 to L5 will be described.

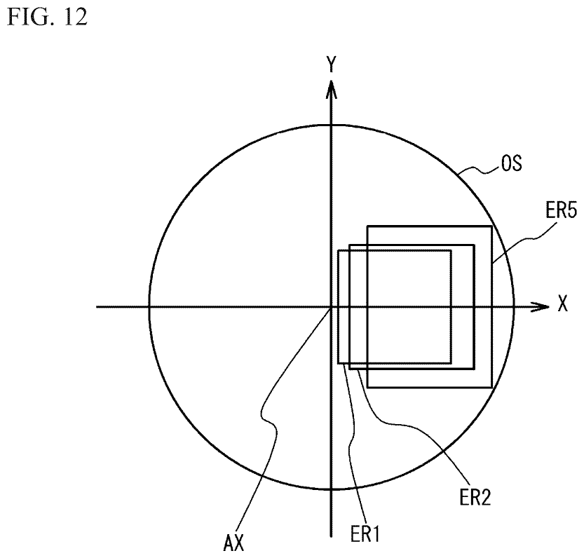

In the present embodiment, the projection optical system 130 is an off-axis optical system that is one-side telecentric (the spatial light modulator 121 side is non-telecentric) for optical path separation by the reflective spatial light modulator 121. As illustrated in FIG. 12, for the exposure areas of the off-axis optical system, the centers of the exposure areas ER1, ER2, and ER5 of respective light beams L1, L2, and L5 are located at positions shifted from the optical axis AX (the center of the lens) of the projection optical system 130 in the X direction (scanning direction). In other words, the pattern images formed by the light beams L1 to L5 are formed at positions shifted from the optical axis AX of the projection optical system 130. This causes an offset in the magnification chromatic aberration in the X direction.

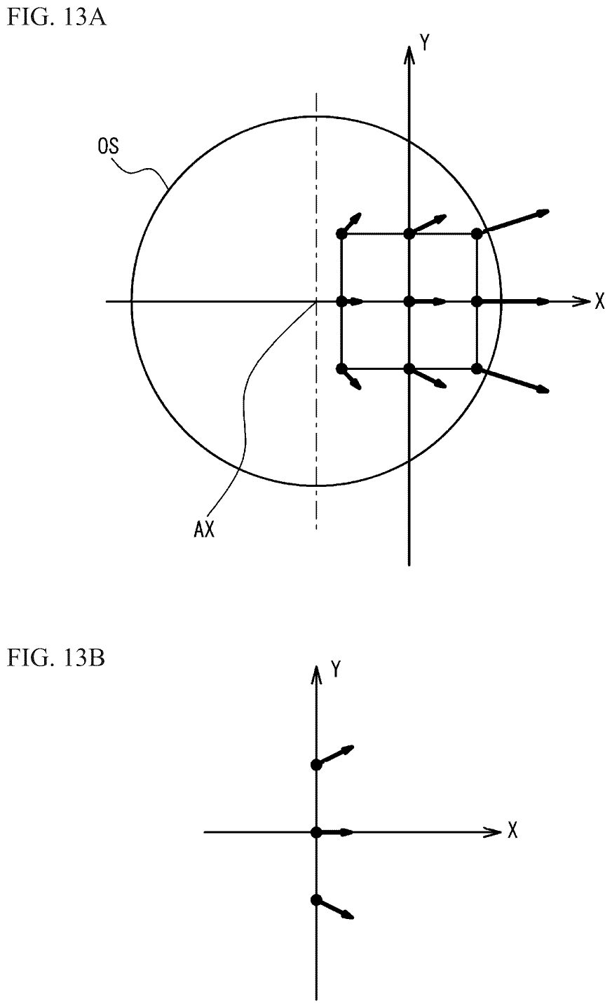

FIG. 13A illustrates the distribution of the magnification chromatic aberration of the projection optical system 130, and FIG. 13B illustrates the distribution of the magnification chromatic aberration after the scan averaging when the scanning in the +X direction is performed. In FIG. 13A and FIG. 13B, arrows are vectors representing the magnification chromatic aberration. A vector representing the magnification chromatic aberration can be expressed by (a×x+b, a×y). Here, a represents a coefficient, b represents an offset, x represents a position in the X direction, and y represents a position in the Y direction.

As illustrated in FIG. 13A, the magnification chromatic aberration increases as the position is farther from the optical axis AX. Here, for example, at y=0, the magnification chromatic aberration in the Y direction is canceled out by the scan averaging effect and becomes 0, but in the X direction, as illustrated in FIG. 13B, an offset (b) of the magnification chromatic aberration remains.

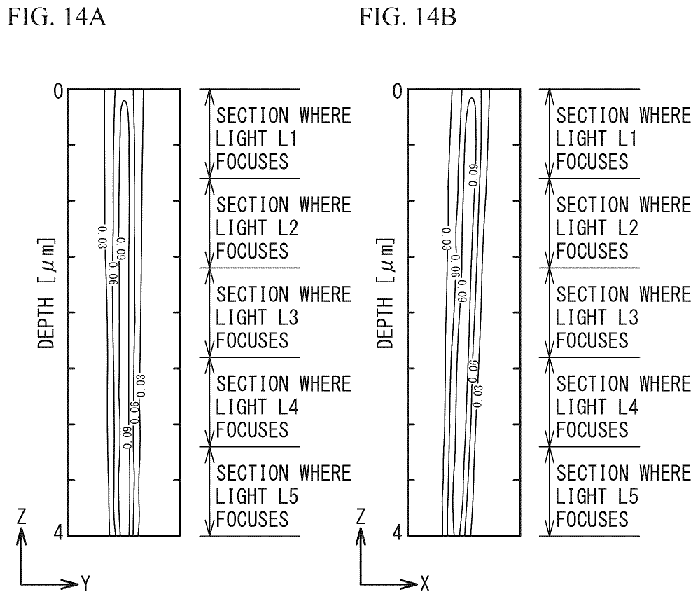

FIG. 14A and FIG. 14B illustrates the simulation results of the intensity distribution of a combined pattern image formed in the resist 602 after scan averaging, where FIG. 14A illustrates the intensity distribution on a plane perpendicular to the X axis at y=0, and FIG. 14B illustrates the intensity distribution on a plane perpendicular to the Y axis.

As illustrated in FIG. 14A, the combined pattern image is not affected by the magnification chromatic aberration on the plane perpendicular to the X axis due to the scan averaging effect, but as illustrated in FIG. 14B, the combined pattern image is affected by the magnification chromatic aberration on the plane perpendicular to the Y axis, and the combined pattern image is inclined. Specifically, in the traveling direction of the light beams L1 to L5, as the positions of the pattern images of the light beams L1 to L5 are farther from the resist 602, the pattern images are formed at farther positions from the optical axis AX in the X direction. As a result, the pattern formed in the resist 602 by the scanning exposure has an inclined inner wall (cross section).

Therefore, in the present embodiment, the timings at which the light beams L1 to L5 are emitted are made different from each other. Specifically, in the traveling direction of the light beams L1 to L5, as the position of the pattern image formed by each of the light beams L1 to L5 is farther from the surface of the resist 602, the emission timing is delayed more.

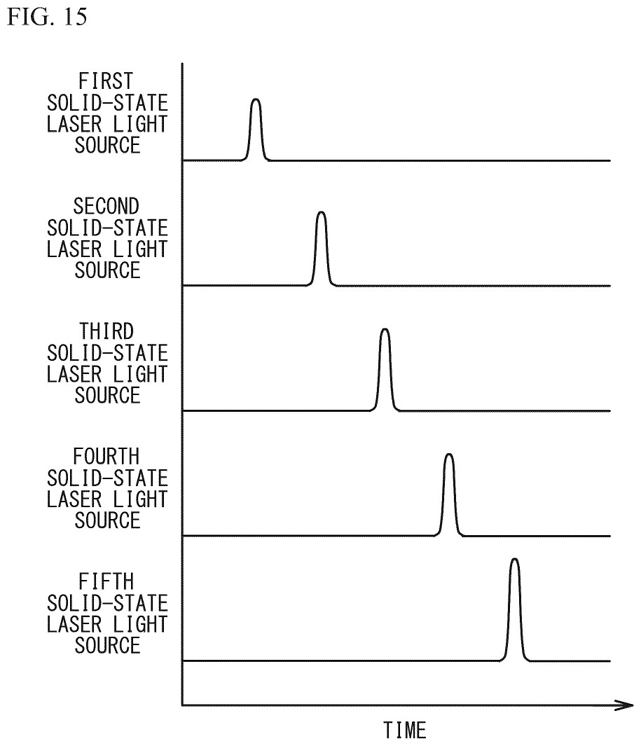

FIG. 15 illustrates the emission timings of the light beams L1 to L5. In the present embodiment, since the formation positions of the pattern images are farther from the surface of the resist 602 in the order of the light beams L5 to L1, the exposure control unit 160 controls the emission timings of the light beams L1 to L5 from the first to fifth solid-state laser light source SLS1 to SLS5 so that the light beam L5 is emitted last and the light beam L1 is emitted first. As a result, as the position of the pattern image formed by a light beam is farther from the surface of the resist 602, the timing of irradiation of the light beam onto the resist 602 becomes later. That is, the timing at which the resist 602 is irradiated with the light beam L1 is the earliest, and the timing at which the resist 602 is irradiated with the light beam L5 is the latest. By adjusting (changing) the timings at which the resist 602 of the wafer W is irradiated with the light beams L1 to L5 in accordance with the scanning direction and the scanning speed of the wafer W, the pattern images of the light beams L1 to L5 can be formed at substantially the same position in the scanning direction (+X direction). For example, in a case where the formation position of the pattern image of the light beam L1 and the formation position of the pattern image of the light beam L2 are different by ΔX in the scanning direction (+X direction), the formation position of the pattern image of the light beam L1 and the formation position of the pattern image of the light beam L2 can be substantially aligned on the wafer W in the scanning direction (+X direction) by irradiating the resist 602 with the light beam L2 at a timing when the wafer W is moved by ΔX by scanning after the resist 602 is irradiated with the light beam L1.

In the case where the scanning direction of the wafer W is the −X direction, the timing at which the resist 602 is irradiated with a light beam is earlier as the formation position of the pattern image by the light beam is farther from the surface of the resist 602. For example, as disclosed in the above-mentioned U.S. Pat. No. 8,089,616, in a case where scanning exposure is performed by raster scanning while switching the scanning direction to the opposite direction, the timings of the instructions (trigger signals) to the solid-state laser light sources SLS1 to SLS5 that emit light beams of different wavelengths may be changed according to the scanning direction.

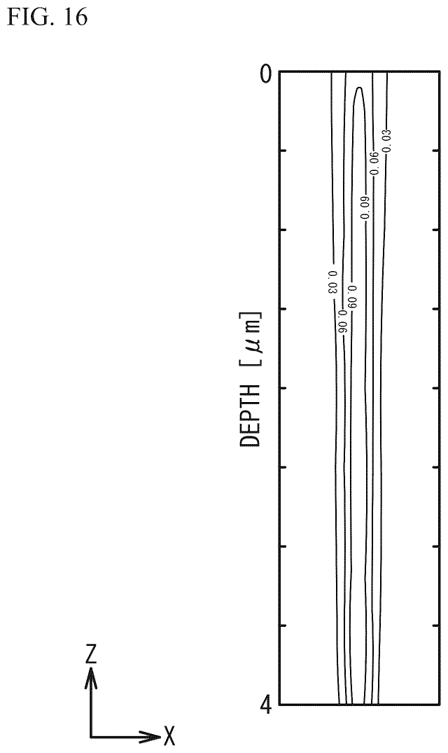

FIG. 16 illustrates simulation results of the intensity of a combined pattern image after scan averaging in a cross section orthogonal to the Y axis, which is obtained by shifting the emission timings of the light beams L1 to L5 as illustrated in FIG. 15.

As illustrated in FIG. 16, as the position of the pattern image formed by each of the light beams L1 to L5 is farther from the surface of the resist 602, the emission timing (the timing of irradiating the resist 602) is delayed more, whereby the offset of the magnification chromatic aberration can be corrected, and the inclination of the combined pattern image in the X direction (scanning direction) can be reduced.

As described above in detail, according to the present embodiment, the exposure device 100 includes the illumination optical system 112 that illuminates the spatial light modulator 121 with the illumination light IL including the light beams L1 to L5 having the wavelengths λ1 to λ5 different from each other, respectively, and the projection optical system 130 that projects the image of the pattern generated by the spatial light modulator 121 onto the wafer with the illumination light IL from the spatial light modulator 121. The projection optical system 130 forms images of the pattern generated by the spatial light modulator 121 with the illumination light L1 to the illumination light L5 from the spatial light modulator 121, respectively, and forms the pattern images of the illumination light L1 to the illumination light L5 at positions farther from the surface of the wafer W in the order of the illumination light L5 to the illumination light L1 in the traveling direction of the illumination light L1 to the illumination light L5. Further, the intensities of the illumination light L1 to the illumination light L5 irradiated onto the wafer W are higher in the order of the illumination light L5 to the illumination light L1.

The positions where the pattern images of the illumination light L1 to the illumination light L5 are formed are farther from the surface of the wafer W in the order of the illumination light L5 to the illumination light L1 in the traveling direction of the illumination light L1 to the illumination light L5. By combining the pattern images of the illumination light L1 to L5, a combined pattern image that is long in the depth direction of the resist 602 can be formed. Further, since the intensities of the illumination light L1 to the illumination light L5 with which the wafer W are irradiated are higher in the order of the illumination light L5 to the illumination light L1, it is possible to solve the problem that the intensity becomes lower as the position where the pattern image is formed is farther from the surface of the wafer W due to the attenuation intensity of the resist 602, and to form a combined pattern image having a uniform intensity in the depth direction of the resist 602. Accordingly, a pattern (groove) having a high aspect ratio with a constant width in the depth direction can be formed in the resist 602.

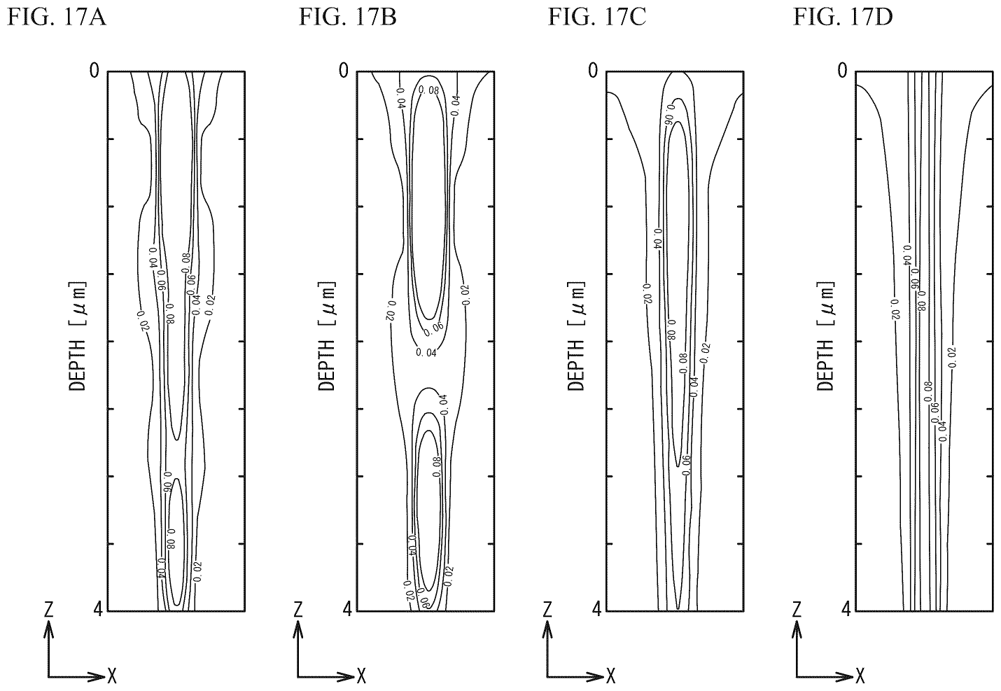

This point will be described in more detail. FIG. 17A to FIG. 17C illustrate simulation results of the intensity of a combined pattern image formed in the resist 502 by methods according to Comparative Examples 1 to 3, respectively, and FIG. 17D illustrates a simulation result of the intensity of a combined pattern image formed in the resist 502 by the method according to the present embodiment.

More specifically, FIG. 17A illustrates the simulation result of the intensity of a combined pattern image formed in the resist 502 when the mask 503 is illuminated with one light beam having a predetermined peak wavelength and the wafer W is continuously moved by about 2.3 μm in the depth direction during exposure (Comparative Example 1). FIG. 17B illustrates the simulation result of the intensity of a combined pattern image formed in the resist 502 when the mask 503 is illuminated with two light beams having different peak wavelengths (Comparative Example 2). The mask 503 was assumed to be illuminated with the two light beams with the same intensity. FIG. 17C illustrates the simulation result of the intensity of a combined pattern image formed in the resist 502 when the mask 503 is illuminated with five light beams having different peak wavelengths (Comparative Example 3). The mask 503 was assumed to be illuminated with five light beams with the same intensity. FIG. 17D illustrates the simulation result of the intensity of a combined pattern image formed in the resist 502 when the mask 503 is illuminated with five light beams having different peak wavelengths by performing the intensity control according to the present embodiment.

As is clear from FIG. 17A to FIG. 17D, a combined pattern image having a uniform intensity distribution in the depth direction can be formed by the intensity control according to the present embodiment. The uniformity (1σ) of the intensity in the depth direction was 38.8% in Comparative Example 1 (FIG. 17A), 50.5% in Comparative Example 2 (FIG. 17B), 23.7% in Comparative Example 3 (FIG. 17C), and 1.2% in the present embodiment (FIG. 17D).

In addition, in the present embodiment, the exposure device 100 includes the exposure control unit 160 that controls the light source unit 111 that supplies the illumination light IL to the illumination optical system 112, and the exposure control unit 160 controls the timings at which the wafer W is irradiated with the illumination light L1 to L5 to be later in the order of the illumination light L5 to the illumination light L1.

Due to the offset of the magnification chromatic aberration of the projection optical system 130, the positions where the pattern images of the illumination light L1 to the illumination light L5 are formed are farther from the optical axis AX of the projection optical system 130 in the order of the illumination light L5 to the illumination light L1 in the scanning direction (X direction). Therefore, by making the timings at which the wafer W is irradiated with the illumination light L1 to the illumination light L5 later in the order of the illumination light L5 to the illumination light L1, the pattern images of the illumination light L1 to the illumination light L5 can be formed at substantially the same position in the scanning direction by scanning the wafer W, and a high-aspect-ratio pattern substantially parallel to the depth direction of the resist 602 can be formed.

In the above embodiment, the five light beams L1 to L5 having different wavelengths from each other are used as the illumination light IL, but this does not intend to suggest any limitation. The number of light beams included in the illumination light IL may be two or more. For example, in the case of the illumination light IL including the light beam L1 with a wavelength λ1 and the light beam L2 with a wavelength λ2 different from the wavelength λ1, the projection optical system 130 forms an image of the pattern generated by the spatial light modulator 121 with the illumination light L1 from the spatial light modulator 121, and forms an image of the pattern generated by the spatial light modulator 121 with the illumination light L2 from the spatial light modulator 121 at a position farther from the surface of the wafer W than the image of the pattern by the illumination light L1 in the traveling direction of the illumination light L2. At this time, the intensity of the illumination light L2 with which the wafer W is irradiated is adjusted to be higher than the intensity of the illumination light L1 with which the wafer W is irradiated. Further, the exposure control unit 160 controls the timing at which the wafer W is irradiated with the illumination light L2 later than the timing at which the wafer W is irradiated with the illumination light L1.

The number of light beams included in the illumination light IL may be determined based on the characteristics (attenuation coefficient, thickness) of the resist 602 of the wafer W, the aspect ratio of the pattern formed on the resist 602, and the like.

Although the projection optical system 130 is used in the above embodiment in which the chromatic aberration is corrected so that the image formation position moves away from the projection optical system 130 as the wavelength increases, the state where the chromatic aberration of the projection optical system is corrected may be a state where the chromatic aberration is corrected so that the image formation position moves away from the projection optical system 130 as the wavelength decreases, or may be a state where the chromatic aberration is corrected so that the image formation position moves away from or approaches the projection optical system 130 as the wavelength moves away from a specific wavelength (for example, the wavelength λ3). Similarly, in the above embodiment, the projection optical system 130 is used in which the chromatic aberration is corrected so that the magnification increases as the wavelength increases, but the state where the chromatic aberration of the projection optical system is corrected may be a state where the chromatic aberration is corrected so that the magnification increases as the wavelength decreases, or may be a state where the chromatic aberration is corrected so that the magnification increases or decreases as the wavelength moves away from a specific wavelength (for example, the wavelength λ3).

In the above embodiment, the exposure control unit 160 performs both the intensity control and the emission timing control, but may perform only one of the controls.

In the above embodiment, the emission timing control of the light beams L1 to L5 has been described by taking the case where the projection optical system 130 is one side telecentric as an example, but the emission timing control can be applied not only to the case where the projection optical system 130 is one side telecentric but also to the case where an offset remains in the magnification chromatic aberration after scan averaging.

Further, in the embodiment above, the case has been described where the exposure device 100 is an exposure device using an SLM, but the exposure device 100 may be an exposure device using a reticle (photomask). In this case, the exposure device 100 exposes a resist (photosensitive material layer) of the wafer W with a pattern formed on a reticle.

In the above embodiment, the case where a combined pattern image with a uniform intensity distribution in the depth direction has been described, but there are cases in which the uniform intensity distribution is not necessarily ideal. In this case, a combination of necessary wavelengths and intensities may be selected so as to obtain an ideal intensity distribution.

Further, although the above embodiment focuses on the combined intensity distribution, a combination of necessary wavelengths and intensities may be selected so that the cross section of the resist 602 after development has a desired shape.

In the above embodiment, the wavelengths of the light beams L1 to L5 are preferably spaced at equal intervals, but may not be necessarily spaced at equal intervals. Further, in the above embodiment, the emission timings of the light beams L1 to L5 are preferably equally spaced in the case where the wavelengths of the light beams L1 to L5 are equally spaced, but the emission timings may not be necessarily equally spaced. Further, in the case where the wavelengths of the light beams L1 to L5 are not equally spaced, the emission timings of the light beams L1 to L5 may not be necessarily equally spaced.

The above-described embodiment is a preferred example of the present disclosure. However, the present disclosure is not limited to this, and various modifications can be made without departing from the scope of the present disclosure.

What is claimed is:

1. An exposure method comprising:
illuminating a first object with exposure light including first exposure light having a first peak wavelength and second exposure light having a second peak wavelength, the second peak wavelength being different from the first peak wavelength; and
exposing a second object with the exposure light from the first object,
wherein a ratio between an intensity of the second exposure light with which the second object is irradiated and an intensity of the first exposure light with which the second object is irradiated is variable, and the intensity of the second exposure light with which the second object is irradiated is set to be higher than the intensity of the first exposure light with which the second object is irradiated.

2. The exposure method according to claim 1, wherein the exposing includes positioning a position of a focal point of the second exposure light farther from an incident surface of the second object on which the exposure light is incident than a position of a focal point of the first exposure light in a traveling direction of the second exposure light.

3. The exposure method according to claim 1, wherein the exposing includes projecting the exposure light from the first object onto the second object by a projection optical system.

4. The exposure method according to claim 3, wherein a second image formed by the first exposure light from the first object overlaps a first image formed by the second exposure light from the first object in a direction intersecting an optical axis of the projection optical system.

5. The exposure method according to claim 1,
wherein the exposure light includes exposure light having a plurality of peak wavelengths including the first peak wavelength and the second peak wavelength,
wherein a difference Δλ between adjacent peak wavelengths in the exposure light having the plurality of peak wavelengths is represented by
$$Δ λ = {k}_{2} \times λ / ( Cz \times {NA}^{2} ) ,$$
where k₂ is a coefficient, NA is a numerical aperture, Cz is axial chromatic aberration, and λ is a specific peak wavelength within a range including the plurality of peak wavelengths, and
wherein k₂ is 1.3 to 1.6.

6. The exposure method according to claim 5, wherein the plurality of peak wavelengths of the exposure light having the plurality of peak wavelengths are equally spaced.

7. The exposure method according to claim 1, wherein a timing at which the second object is irradiated with the second exposure light is different from a timing at which the second object is irradiated with the first exposure light.

8. An exposure method comprising:
illuminating a first object with exposure light including first exposure light having a first peak wavelength and second exposure light having a second peak wavelength, the second peak wavelength being different from the first peak wavelength; and
exposing a second object moving along a scanning direction with the exposure light from the first object,
wherein a timing at which the second object is irradiated with the second exposure light is different from a timing at which the second object is irradiated with the first exposure light.

9. The exposure method according to claim 8, wherein the exposing includes positioning a position of a focal point of the second exposure light farther from an incident surface of the second object on which the exposure light is incident than a position of a focal point of the first exposure light in a traveling direction of the second exposure light.

10. The exposure method according to claim 8, wherein the exposing includes projecting the exposure light from the first object onto the second object by a projection optical system.

11. The exposure method according to claim 10, wherein the projection optical system is an optical system that is non-telecentric at a side of the first object.

12. The exposure method according to claim 10, wherein each of a center of an exposure area of the first exposure light and a center of an exposure area of the second exposure light is positioned at a position shifted from an optical axis of the projection optical system.

13. The exposure method according to claim 1, wherein the first object is a mask on which a pattern is formed or a spatial light modulator that generates the pattern.

14. The exposure method according to claim 1,
wherein the intensity of the first exposure light is adjusted by controlling a first light source, and
wherein the intensity of the second exposure light is adjusted by controlling a second light source different from the first light source.

15. The exposure method according to claim 1, wherein the second peak wavelength is longer than the first peak wavelength.

16. The exposure method according to claim 1,
wherein the second object includes a photosensitive material layer having an incident surface on which the exposure light is incident, and
wherein the intensity of the first exposure light and the intensity of the second exposure light are set according to properties of the photosensitive material layer.

17. The exposure method according to claim 16, wherein the properties include a thickness of the photosensitive material layer.

18. An exposure device comprising:
an illumination optical system that illuminates a first object with exposure light including first exposure light having a first peak wavelength and second exposure light having a second peak wavelength, the second peak wavelength being different from the first peak wavelength; and
a projection optical system that projects the exposure light from the first object onto a second object,
wherein a ratio between an intensity of the second exposure light with which the second object is irradiated and an intensity of the first exposure light with which the second object is irradiated is variable, and the intensity of the second exposure light with which the second object is irradiated is set to be higher than the intensity of the first exposure light with which the second object is irradiated.

19. The exposure device according to claim 18, wherein a position of a focal point of the second exposure light is positioned farther from an incident surface of the second object on which the exposure light is incident than a position of a focal point of the first exposure light in a traveling direction of the second exposure light.

20. The exposure device according to claim 18, further comprising:
a control device that causes a light source that supplies the exposure light to the illumination optical system to perform control such that the intensity of the second exposure light with which the second object is irradiated is higher than the intensity of the first exposure light with which the second object is irradiated.

21. An exposure device that scans and exposes a pattern of a first object onto a second object, the exposure device comprising:
an illumination optical system that illuminates a first object with exposure light including first exposure light having a first peak wavelength and second exposure light having a second peak wavelength, the second peak wavelength being different from the first peak wavelength;
a projection optical system that projects the exposure light from the first object onto a second object moving along a scanning direction; and
a control device that controls a light source that supplies the exposure light to the illumination optical system,
wherein the control device performs control such that a timing at which the second object is irradiated with the second exposure light is different from a timing at which the second object is irradiated with the first exposure light.

22. The exposure device according to claim 21, wherein a position of a focal point of the second exposure light is positioned farther from an incident surface of the second object on which the exposure light is incident than a position of a focal point of the first exposure light in a traveling direction of the second exposure light.

23. The exposure device according to claim 20, wherein the light source includes a first light source that adjusts the intensity of the first exposure light, and a second light source that is different from the first light source and adjusts the intensity of the second exposure light.

24. A device manufacturing method comprising:
exposing a photosensitive material layer of a second object by using the exposure method according to claim 1; and
processing a part further in than the photosensitive material layer of the second object by using a pattern generated by developing the photosensitive material layer, which has been exposed, as a mask.

25. The exposure device according to claim 18, wherein the first object is a mask on which the pattern is formed or a spatial light modulator that generates the pattern.

26. The exposure device according to claim 18, wherein the second peak wavelength is longer than the first peak wavelength.

27. The exposure device according to claim 18,
wherein the second object includes a photosensitive material layer having an incident surface on which the exposure light is incident, and
wherein the intensity of the first exposure light and the intensity of the second exposure light are set according to properties of the photosensitive material layer.

28. The exposure device according to claim 27, wherein the properties include a thickness of the photosensitive material layer.
